(19) United States
(12) Patent Application Publication
(10) Pub. No.: US 2025/0347812 A1
(43) Pub. Date: Nov. 13, 2025

(54) ToF CAMERA MODULE AND CAMERA DEVICE

(71) Applicant: LG ELECTRONICS INC., Seoul (KR)

(72) Inventors: Chanyong PARK, Seoul (KR); Junghee EIM, Seoul (KR); Eunsung LEE, Seoul (KR)

(73) Assignee: LG ELECTRONICS INC., Seoul (KR)

(21) Appl. No.: 19/076,232

(22) Filed: Mar. 11, 2025

(30) Foreign Application Priority Data
May 8, 2024 (KR) 10-2024-0060475
Oct. 14, 2024 (WO) PCT/KR2024/015485

(51) Int. Cl. G01S 17/894; G01S 7/481; G01S 17/86; H04N 23/45; H04N 23/51

(52) U.S. Cl. CPC G01S 17/894; G01S 7/4813; G01S 17/86; H04N 23/45; H04N 23/51

(57) ABSTRACT

The present disclosure relates to a time of flight (ToF) camera module and a camera device. The camera device includes a body forming an accommodation space, and a ToF camera module located in the accommodation space. The ToF camera module includes a light source unit located on one surface of a first substrate, a ToF lens unit receiving light emitted from the light source unit, a ToF sensor unit located on one surface of a second substrate connected to the first substrate by a first connector, and receiving light passing through the ToF lens unit, and an idle space formed on a side of the other surface of the first substrate. The light source unit and the ToF lens unit are located in a first layer, and the ToF sensor unit is located in a second layer different from the first layer.

### CROSS-REFERENCE TO RELATED APPLICATIONS

Pursuant to 35 U.S.C. § 119, this application claims the benefit of an earlier filing date and right of priority to Korean Patent Application No. 10-2024-0060475, filed on May 8, 2024, and International Application No. PCT/KR2024/015485, filed on Oct. 14, 2024, the contents of which are all incorporated by reference herein in their entirety.

### TECHNICAL FIELD

The present disclosure relates to a time of flight (ToF) camera module and a camera device, and more particularly, to a ToF camera module and a three-dimensional (3D) vision camera device including the same.

### BACKGROUND

In recent years, research has been increasingly focused on three-dimensional (3D) cameras capable of obtaining information about the distance from an object, especially devices for obtaining a 3D depth image for facial recognition.

In line with this trend, a time of flight (ToF) module has been introduced as a depth image acquisition device. The ToF module measures the ToF of light irradiated to an object and then reflected from the object to a light receiver, thereby obtaining a depth image.

However, as the distance from the object increases, noise and distortion occur, resulting in a rapid decrease in the accuracy of depth information and a decrease in correlation with a color image. To solve the problem, there were attempts to correct a depth image by placing a red, green, blue (RGB) module adjacent to a ToF sensor.

However, there is still a need for a technique for an efficient arrangement relationship between the RGB module and the ToF sensor.

### SUMMARY

Accordingly, the present disclosure is directed to a time of flight (ToF) camera module and a camera device that substantially obviate one or more problems due to limitations and disadvantages of the related art.

An aspect of the present disclosure is to provide a ToF camera module capable of efficiently transferring heat generated from a ToF camera to the outside.

Another aspect of the present disclosure is to provide a camera device capable of efficiently transferring heat generated from a ToF camera to the outside.

The objects to be achieved by the present disclosure are not limited to what has been particularly described hereinabove and other objects not described herein will be more clearly understood by persons skilled in the art from the following detailed description.

To achieve these objects and other advantages and in accordance with the purpose of the disclosure, as embodied and broadly described herein, a ToF camera module includes a light source unit located on one surface of a first substrate, a ToF lens unit receiving light emitted from the light source unit, a ToF sensor unit located on one surface of a second substrate connected to the first substrate by a first connector, and receiving light passing through the ToF lens unit, and an idle space formed on a side of the other surface of the first substrate. The light source unit and the ToF lens unit are located in a first layer, and the ToF sensor unit is located in a second layer different from the first layer.

According to embodiments, the second substrate may include an area where the ToF sensor unit is located and a cut area where the ToF sensor unit is not located, and the idle space may be formed by the cut area.

According to embodiments, the first connector may be bent to connect the first substrate and the second substrate.

According to embodiments, the ToF camera module may further include a housing having a front surface on which the light source unit and the ToF lens unit are at least partially exposed and having the ToF sensor unit located thereinside.

According to embodiments, a rear surface of the housing may include a first surface and a second surface stepped with the first surface, and the first surface may be formed within the idle space.

According to embodiments, the ToF camera module may further include a third substrate receiving power from an outside, and a second connector connecting the third substrate and the second substrate. The first substrate and the second substrate may receive power from the third substrate through the second connector.

According to another aspect of the present disclosure, a camera device includes a body forming an accommodation space, and a ToF camera module located in the accommodation space. The ToF camera module includes a light source unit located on one surface of a first substrate, a ToF lens unit receiving light emitted from the light source unit, a ToF sensor unit located on one surface of a second substrate connected to the first substrate by a first connector, and receiving light passing through the ToF lens unit, and an idle space formed on a side of the other surface of the first substrate. The light source unit and the ToF lens unit are located in a first layer, and the ToF sensor unit is located in a second layer different from the first layer.

According to embodiments, the second substrate may include an area where the ToF sensor unit is located and a cut area where the ToF sensor unit is not located, and the idle space may be formed by the cut area.

According to embodiments, the ToF camera module may further include a housing having a front surface on which the light source unit and the ToF lens unit are at least partially exposed and having the ToF sensor unit located thereinside. A rear surface of the housing may include a first surface and a second surface stepped with the first surface, and the first surface may be formed within the idle space.

According to embodiments, the camera device may further include a rear cover having a front surface meeting a rear surface of the ToF camera module.

According to embodiments, the front surface of the rear cover may include a protruding surface meeting the first surface and a mounting surface meeting the second surface, and the protruding surface may be formed to protrude further than the mounting surface.

According to embodiments, the camera device may further include a top cover forming a top surface of the body and coupled with the body, the top cover may include a heat sink formed to extend in a first direction on an exterior thereof, and a plurality of heat sinks may be arranged spaced apart from each other in a second direction perpendicular to the first direction.

According to embodiments, the top cover may further include a first contact portion meeting at least a portion of a rear surface of the rear cover.

According to embodiments, the rear cover may include a rib formed to protrude on the rear surface thereof and having a top surface meeting a bottom surface of the first contact portion, and the top cover may further include a protrusion formed to protrude on the bottom surface of the first contact portion and having one surface meeting the protruding surface of the rib.

According to embodiments, the camera device may further include a printed circuit board (PCB) located in the accommodation space and having an electronic component mounted on one surface thereof, and a red, green, blue (RGB) camera module located in the accommodation space. The ToF camera module may be located on a side of one surface of the PCB, the RGB camera module may be located on a side of the other surface of the PCB, and a front surface of the ToF camera module and a front surface of the RGB camera module may form a single plane.

According to embodiments, the RGB camera module may include a driving component for driving the RGB camera module, and the driving component may be located on the side of the other surface of the PCB, spaced apart from the PCB.

According to embodiments, the camera device may further include a front cover forming a front surface of the body and coupled with the body, and the front cover may include an accommodation portion for accommodating the ToF camera module and the RGB camera module.

According to embodiments, the camera device may further include a front glass covering a front of the front cover, and a mask may be formed on a portion of the front glass other than a portion where the ToF camera module and the RGB camera module are exposed.

According to embodiments, there is an effect of preventing the degradation of camera performance caused by heat generation by providing a ToF camera module capable of efficiently transferring heat generated from a ToF camera to the outside.

According to embodiments, there is an effect of preventing the degradation of camera performance caused by heat generation by providing a camera device capable of efficiently transferring heat generated from a ToF camera to the outside.

The effects that are achievable by the present disclosure are not limited to what has been particularly described hereinabove and other advantages not described herein will be more clearly understood by persons skilled in the art from the following description.

### BRIEF DESCRIPTION OF DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a diagram illustrating a camera device according to embodiments;

FIG. 2 is an exploded view illustrating a camera device according to embodiments;

FIGS. 3 and 4 are diagrams illustrating positions at which a time of flight (ToF) camera module and a red, green, blue (RGB) camera module are arranged in a camera device according to embodiments;

FIGS. 5 and 6 are diagrams illustrating a ToF camera module according to embodiments;

FIG. 7 is a cross-sectional view illustrating a ToF camera module according to embodiments;

FIG. 8 is a diagram illustrating a substrate of a ToF camera module according to embodiments;

FIG. 9 is a diagram illustrating a direction in which heat generated within a ToF camera module is transferred according to embodiments;

FIG. 10 is a diagram illustrating a rear cover according to embodiments;

FIGS. 11 and 12 are diagrams illustrating a top cover according to embodiments;

FIG. 13 is a diagram illustrating a rear cover according to embodiments;

FIG. 14 is a diagram illustrating a top cover according to embodiments;

FIG. 15 is a partial cross-sectional view illustrating a camera device according to embodiments; and

FIG. 16 is a diagram illustrating directions in which heat generated within a camera device is transferred according to embodiments.

### DETAILED DESCRIPTION

Embodiments of the present disclosure will be described in detail with reference to the attached drawings. Like reference numerals are assigned to the same or similar components regardless of drawing numbers, and their redundant description will be avoided.

Suffixes such as “module” and “unit” for components in the following description are merely intended to facilitate the description of the specification, and do not give any special meanings or functions. Lest it should obscure the subject matter of an embodiment of the present disclosure, well-known technologies will not be described in detail in describing the embodiment of the present disclosure.

The accompanying drawings are used to help easily understand embodiments of the present disclosure, not limiting the technical features of the present disclosure, and the present disclosure should be construed to encompass any alterations, equivalents and substitutes within the scope and spirit of the present disclosure.

Although as used herein, such terms as “1st” and “2nd”, or “first” and “second” may be used to describe various components, they do not limit the components. The terms simply distinguish a corresponding component from another.

It is to be understood that if a component is referred to as “coupled with”, “coupled to”, “connected with”, or “connected to” another component, it means that the component may be coupled with the other element directly or via a third component. On the contrary, it is to be understood that if a component is referred to as “directly coupled with”, “directly coupled to”, “directly connected with”, or “directly connected to” another component, it means that the component may be coupled with the other element without a third component in between.

A singular form of a noun corresponding to an item may include one or more of the things, unless the relevant context clearly indicates otherwise.

It is to be appreciated that as used herein, terms such as “include” or “has” are intended to specify the existence of a feature, a number, a step, an operation, a component, a part, or a combination thereof set forth in the specification, and do not exclude the existence or possibility of addition of one or more other features, numbers, steps, operations, components, parts, or combinations thereof.

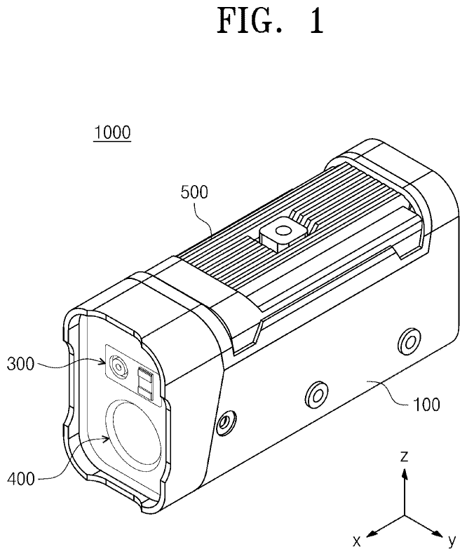

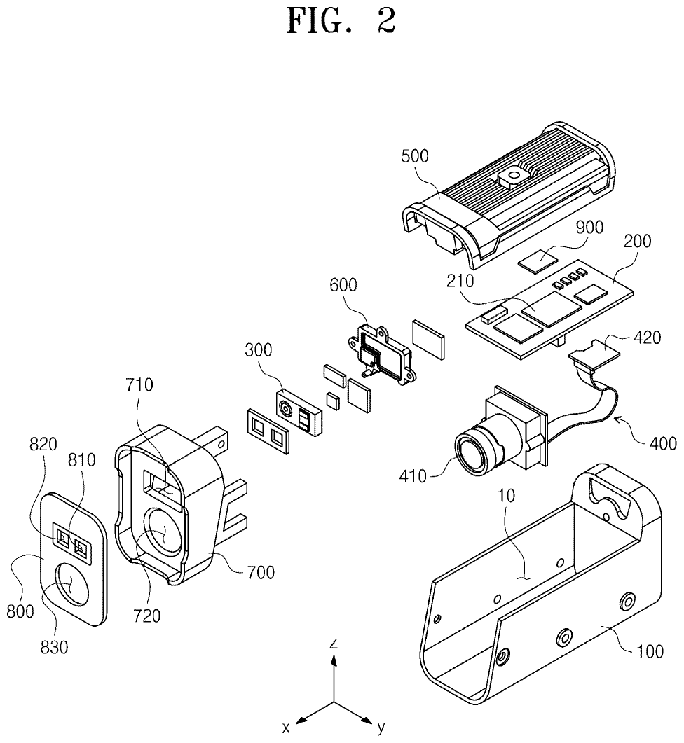

FIG. 1 is a diagram illustrating a camera device according to embodiments. FIG. 2 is an exploded view illustrating a camera device according to embodiments.

A camera device 1000 illustrated in FIG. 2 corresponds to a camera device 1000 illustrated in FIG. 1.

A description will be given of the camera device 1000 according to embodiments with the appreciation that a front-rear direction is based on an x-axis direction, a left-right direction or a lateral direction is based on a y-axis direction, and an up-down direction or a height direction is based on a z-axis direction.

Referring to FIGS. 1 and 2, the camera device 1000 according to the embodiments may include a body 100, a printed circuit board (PCB) 200, a time of flight (ToF) module 300, a red, green, blue (RGB) camera module 400, a top cover 500, a rear cover 600, and a front cover 700.

The camera device 1000 according to the embodiments may correspond to a three-dimensional (3D) vision camera that captures a 3D image including depth information. Unlike a general two-dimensional (2D) camera that provides flat image information, the 3D vision camera may recognize the position and shape of an object in a real space, including distance information between the object and the camera. More specifically, the camera device 1000 according to the embodiments may correspond to a 3D dimension vision camera using a ToF camera.

The body 100 may form an accommodation space 10, and the PCB 200, the ToF camera module 300, the RGB camera module 400, the rear cover 600, and so on may be built in the accommodation space 10. The body 100 may be formed to be elongated in the x-axis direction, and include a side surface including a bottom surface, and a rear surface, as illustrated in FIGS. 1 and 2.

The PCB 200 may be located inside the accommodation space 10, and an electronic component 210 may be mounted on one surface of the PCB 200. More specifically, the electronic component 210 may be mounted on a top surface of the PCB 200. The electronic component 210 may include, for example, a controller including an application processor (AP) for operating the camera device 1000.

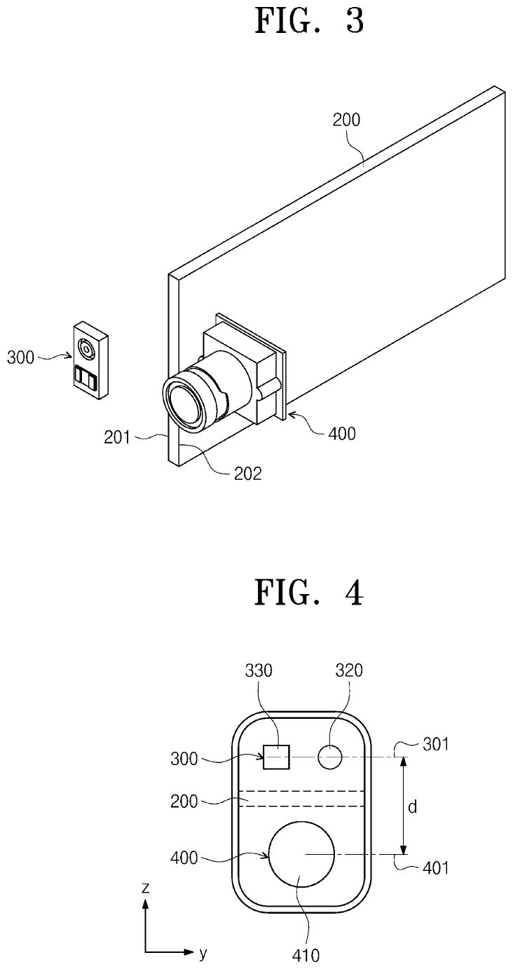

The ToF camera module 300 may be located inside the accommodation space 10 and located on the side of one surface of the PCB 200. More specifically, the ToF camera module 300 may be located in the z-axis direction with respect to the PCB 200. The RGB camera module 400 may be located inside the accommodation space 10 and located on the side of the other surface of the PCB 200. More specifically, the RGB camera module 400 may be located in a −z-axis direction with respect to the PCB 200. The positional relationship between the ToF camera module 300 and the RGB camera module 400 will be described in detail with reference to FIGS. 3 and 4.

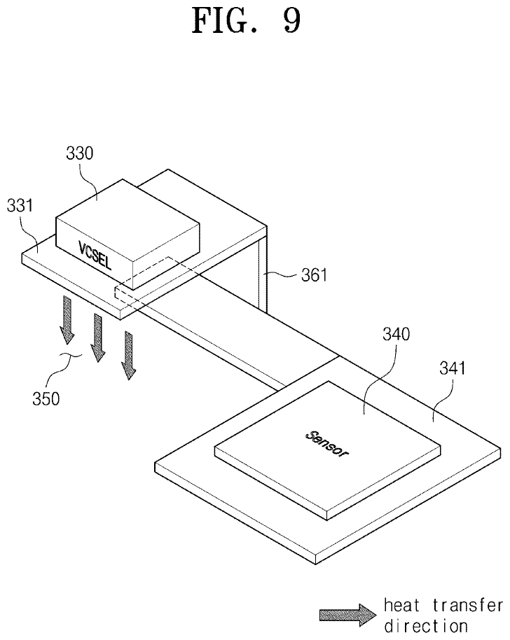

The top cover 500 may form a top surface of the body 100 and be coupled with the body 100. In other words, the top cover 500 may form the accommodation space 10 together with the body 100 by being coupled with the body 100. The top cover 500 may be formed of an aluminum material and transfer heat generated within the camera device 1000 to the outside. More specifically, the top cover 500 may transfer heat generated from the electronic component 210 mounted on the PCB 200 or the ToF camera module 300 to the outside. The configuration of the top cover 500 will be described in detail with reference to FIGS. 9 to 11.

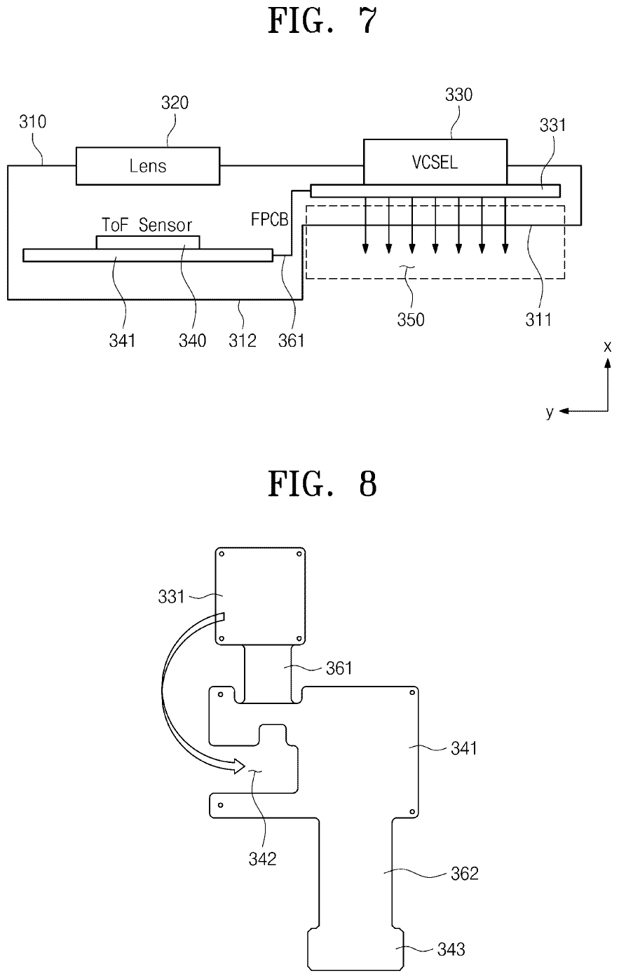

The rear cover 600 may be located inside the accommodation space 10 and have a front surface meeting the rear surface of the ToF camera module 300. That is, the rear cover 600 may cover the rear surface of the ToF camera module 300. The rear cover 600 may be formed of an aluminum material like the top cover 500 and transfer heat generated from the ToF camera module 300 to the outside. More specifically, the rear cover 600 may transfer heat generated from the ToF camera module 300 to the top cover 500, and as a result, the transferred heat may be transferred to the outside through the top cover 500. The configuration of the rear cover 600 will be described in detail with reference to FIGS. 7 and 8.

The front cover 700 may form a front surface of the body 100 and be coupled with the body 100. In other words, the front cover 700 may form the accommodation space 10 together with the body 100 by being coupled with the body 100. In addition, the front cover 700 may include accommodation portions 710 and 720 for accommodating the ToF camera module 300 and the RGB camera module 400.

The front of the front cover 700 may be covered by a front glass 800. A mask may be formed on the front glass 800 except for portions 810, 820, and 830 where the ToF camera module 300 and the RGB camera module 400 are exposed. That is, light may pass through the ToF camera module 300 or the RGB camera module 400, without passing through the other portions.

FIG. 3 and FIG. 4 are diagrams illustrating positions at which a ToF camera module and an RGB camera module are arranged in a camera device according to embodiments. More specifically, FIG. 3 is a perspective view illustrating arrangement positions of the ToF camera module 300 and the RGB camera module 400, and FIG. 4 is a front view illustrating the arrangement positions of the ToF camera module 300 and the RGB camera module 400.

Referring to FIGS. 3 and 4, the ToF camera module 300 and the RGB camera module 400 may be arranged with the PCB 200 therebetween. For example, the ToF camera module 300 may be located on the side of one surface 201 of the PCB 200, and the RGB camera module 400 may be located on the side of the other surface 202 of the PCB 200. That is, the ToF camera module 300 and the RGB camera module 400 may not be located parallel to each other, but above and below each other.

Further, a front surface of the ToF camera module 300 and a front surface of the RGB camera module 400 may form a single plane. More specifically, the ToF camera module 300 may include a light source unit 330 and a ToF lens unit 320 receiving light emitted from the light source unit 330. The RGB camera module 400 may include an RGB lens unit 410 receiving light. The light source unit 330 and the ToF lens unit 320 may form the front surface of the ToF camera module 300, and the RGB lens unit 410 may form the front surface of the RGB camera module 400.

The ToF camera module 300 calculates a distance value to the object based on a time it takes for light emitted through the ToF lens unit 320 to be reflected back from the object. A distance value for each point of the object may be implemented as depth data, and a shape image such as a depth image may be obtained through the depth data.

While the RGB camera module 400 uses external light as a light source, the ToF camera module 300 may emit light having a separate wavelength (e.g., an infrared (IR) wavelength), and the ToF lens unit 320 may receive the emitted light. Therefore, the ToF camera module 300 may separately include the light source unit 330 for emitting light. The light source unit 330 may include, for example, a vertical cavity surface emitting laser (VCSEL). In particular, the light source unit 330 may correspond to a 3-junction VCSEL to increase light output.

In general, an RGB image obtained by the RGB camera and a shape image obtained by the ToF camera may be synthesized, and there may be a mismatched part between an RGB image and depth data due to a parallax between the RGB camera and the ToF camera. This phenomenon is called occlusion.

Occlusion corresponds to one of errors caused by a parallax between a plurality of cameras, and to minimize the occurrence of occlusion, it is necessary to minimize the distance between the cameras forming a synthesized image. Nonetheless, it was common to place cameras without deep consideration of the occurrence of occlusion.

Therefore, the ToF camera module 300 and the RGB camera module 400 may be located above and below each other to minimize the distance between the cameras in the camera device 1000 according to the embodiments.

When the RGB camera module 400 and the ToF camera module 300 are arranged parallel to each other in a straight line, the gap between the RGB camera module 400 and the ToF camera module 300 may not be reduced to a certain range due to the size of the RGB lens unit 410 of the RGB camera module 400 itself.

Therefore, the camera device 1000 according to the embodiments has the effect of reducing the gap between the RGB camera module 400 and the ToF camera module 300 to a certain range by disposing the RGB camera module 400 and the ToF camera module 300 not in a straight line but vertically. The certain range may correspond to a user-desired length.

More specifically, the center of the light source unit 330 and the center of the ToF lens unit 320 may be formed on a first line 301, whereas the center of the RGB lens part 410 may not be formed on the first line 301. That is, a second line 401, which is a line parallel to the first line 301 among multiple straight lines passing through the center of the RGB lens unit 410, may not meet the first line 301.

The ToF camera module 300 and the RGB camera module 400 may be arranged such that the gap between the first line 301 and the second line 401 has a minimum value.

Therefore, the camera device 1000 according to the embodiments may minimize the occurrence of occlusion by minimizing the gap between the ToF camera module 300 and the RGB camera module 400. In addition, the camera device 1000 according to the embodiments may improve a matching rate by minimizing the gap between the ToF camera module 300 and the RGB camera module 400.

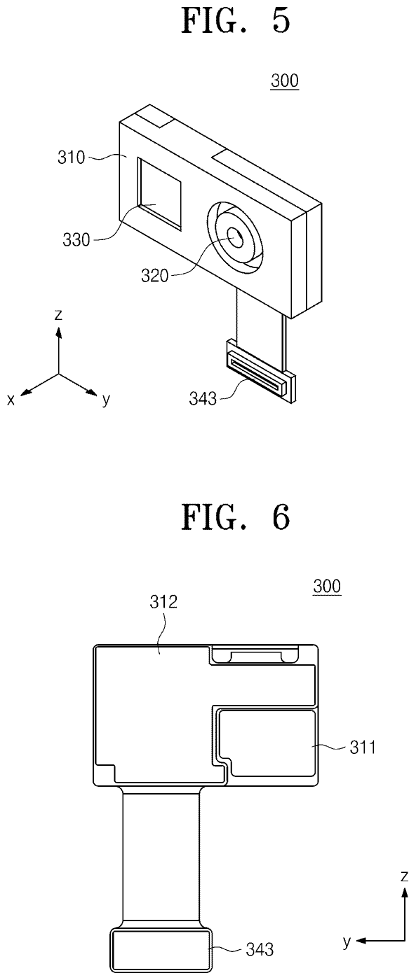

FIG. 5 and FIG. 6 are diagrams illustrating a ToF camera module according to embodiments. More specifically, FIG. 5 is a diagram illustrating the ToF camera module 300 viewed from the front, and FIG. 6 is a diagram illustrating the ToF camera module 300 viewed from the rear.

Referring to FIGS. 5 and 6, the ToF camera module 300 may include a housing 310, the ToF lens unit 320, and the light source unit 330.

The housing 310, which is a component forming the exterior of the ToF camera module 300, may have the ToF lens unit 320 and the light source unit 330 built therein. A front surface of the housing 310 may refer to the front surface of the ToF camera module 300, and a rear surface of the housing 310 may refer to the rear surface of the ToF camera module 300.

The rear surface of the housing 310 may include a first surface 311 and a second surface 312. In other words, the rear surface of the ToF camera module 300 may include the first surface 311 and the second surface 312.

The first surface 311 may be formed to be stepped with the second surface 312 and located closer to the front surface of the ToF camera module 300 than the second surface 312. In other words, the first surface 311 may be formed to be located closer to the front surface of the housing 310 than the second surface 312. The positions of the first surface 311 and the second surface 312 may be determined according to the degree of heat generated from multiple components of the ToF camera module 300 built in the housing 310. For example, the first surface 311 may be formed in an area corresponding to a component that generates a large amount of heat.

In addition, an area occupied by the first surface 311 may be smaller than an area occupied by the second surface 312. That is, the rear surface of the housing 310 or the ToF camera module 300 may be formed to have a portion recessed toward the front surface. For example, as illustrated in FIG. 6, the first surface 311 corresponding to a right corner of the rear surface of the housing 310 or the ToF camera module 300 may be formed at a position closer to the front surface than the second surface 312.

The light source unit 330 may be configured to emit light, and the emitted light may be reflected from the object, as described with reference to FIGS. 3 and 4. The reflected light may be received by the ToF lens unit 320. The light source unit 330 and the ToF lens unit 320 may be exposed at least partially on the front surface of the housing 310.

The ToF camera module 300 will be described in detail with reference to FIGS. 7 to 9.

FIG. 7 is a cross-sectional view illustrating a ToF camera module according to embodiments.

Referring to FIG. 7, the ToF camera module 300 may include the housing 310, the ToF lens unit 320, the light source unit 330, a ToF sensor unit 340, and an idle space 350.

As described above, the housing 310 may have the light source unit 330 and the ToF lens unit 320 at least partially exposed on the front surface thereof, and have the ToF sensor unit 340 located therein.

The light source unit 330 may be located on one surface of a first substrate 331. The ToF lens unit 320 may receive light emitted from the light source unit 330. The ToF sensor unit 340 may be located on one surface of a second substrate 341 connected to the first substrate 331 by a first connector 361, and receive light passing through the ToF lens unit 320.

The light source unit 330 and the ToF lens unit 320 may be located in a first layer, and the ToF sensor unit 340 may be located in a second layer different from the first layer. In other words, the light source unit 330 and the ToF lens unit 320 may be located in the same layer, and the ToF sensor unit 340 may be located in a different layer from the layer where the light source unit 330 and the ToF lens unit 320 are located.

Preferably, the light source unit 330 and the ToF lens unit 320 may be located to be exposed on the front surface of the housing 310, and the ToF sensor unit 340 may be located inside the housing 310. More specifically, the ToF sensor unit 340 may be located close to the rear surface inside the housing 310, and the ToF sensor unit 340 may be located to overlap the ToF lens unit 320.

The idle space 350 may be formed on the side of the other surface of the first substrate 331. That is, the light source unit 330 may be located on one surface of the first substrate 331, and the idle space 350 may be formed on the other surface of the first substrate 331.

The idle space 350 may be formed inside the housing 310, or may be formed outside the housing 310. For example, when the rear surface of the housing 310 is formed as a single flat surface without a step, the idle space 350 may be formed inside the housing 310.

Alternatively, for example, when the rear surface of the housing 310 is formed as the first surface 311 and the second surface 312 which are stepped with each other as described in FIGS. 5 and 6, the idle space 350 may be formed outside the housing 310. In this case, the first surface 311 may be formed inside the idle space 350.

Heat generated from the ToF camera module 300 may be transferred to the outside through the idle space 350. More specifically, heat generated from the light source unit 330 of the ToF camera module 300 may be transferred to the outside through the idle space 350.

In general, a VCSEL that irradiates light generates heat during operation, and the heat generated in this way may cause performance degradation or an accuracy problem. In particular, the consistency of an IR signal may be reduced due to the generated heat, which may eventually lead to a performance problem of the 3D vision camera, among various problems.

In order to solve this problem, the temperature of the VCSEL was lowered using a heat sink. However, there is still a problem that the heat generated from the VCSEL passes through other components within the ToF camera before being transferred to the heat sink, causing malfunctions in other components.

Therefore, the ToF camera module 300 according to the embodiments may include the idle space 350 so that the heat generated from the light source unit 330 does not pass through other components, when transferred to the outside.

FIG. 8 is a diagram illustrating a substrate of a ToF camera module according to embodiments. FIG. 9 is a diagram illustrating a direction in which heat generated within a ToF camera module is transferred according to embodiments. More specifically, FIG. 8 illustrates the substrate before the first substrate 331 rotates, and FIG. 9 illustrates the substrate after the first substrate 331 rotates.

Referring to FIG. 8, the substrate provided inside the ToF camera module 300 may include the first substrate 331, the second substrate 341, and a third substrate 343. The first substrate 331 and the second substrate 341 may be connected by the first connector 361, and the second substrate 341 and the third substrate 343 may be connected by a second connector 362.

The first substrate 331 may be rotated in an arrowed direction and thus located in a different layer from the second substrate 341. As the first substrate 331 is rotated in the arrowed direction, the first connector 361 may be bent. Therefore, the first connector 361 is preferably configured as a flexible printed circuit board (FPCB).

The second substrate 341 may include an area where the ToF sensor unit 340 is located and a cut area 342 where the ToF sensor portion 340 is not located. That is, as illustrated in FIG. 8, the second substrate 341 may be cut and opened in a portion where the ToF sensor unit 340 is not located.

More specifically, the cut area 342 may be formed to overlap with the position where the first substrate 331 is located after rotating in the arrowed direction. That is, the idle space 350 may be formed on the side of the other surface of the first substrate 331 and formed by the cut area 342 at the same time.

Referring to FIG. 9, heat generated from the light source unit 330 may be transferred to the outside through the idle space 350. In particular, the heat generated from the light source unit 330 may be transferred to the outside without passing through the second substrate 341 by the cut area 342 formed on the second substrate 341.

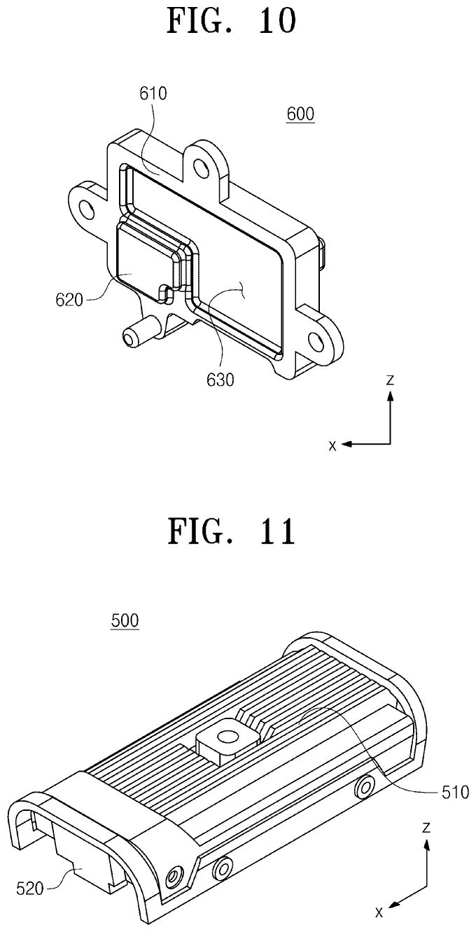

FIG. 10 is a diagram illustrating a rear cover according to embodiments. FIGS. 11 and 12 are diagrams illustrating a top cover according to embodiments. More specifically, FIG. 10 is a diagram illustrating the rear cover 600 viewed from the front, FIG. 11 is a diagram illustrating the top cover 500 viewed from above, and FIG. 12 is a diagram illustrating the top cover 500 viewed from below.

As described before with reference to FIGS. 1 and 2, the rear cover 600 may correspond to a component that covers the rear surface of the ToF camera module 300.

Referring to FIG. 10 together with FIG. 6, the front surface of the rear cover 600 may include a protruding surface 620 that meets the first surface 311 of the rear surface of the ToF camera module 300 and a mounting surface 630 that meets the second surface 312 of the rear surface of the ToF camera module 300. The protruding surface 620 may be formed to protrude further than the mounting surface 630. That is, the front surface of the rear cover 600 that meets the rear surface of the ToF camera module 300 may be formed to correspond to the shape of the rear surface of the ToF camera module 300.

As described before with reference to FIGS. 1 and 2, the rear cover 600 may transfer heat generated from the ToF camera module 300 to the outside by the front surface thereof in contact with the rear surface of the ToF camera module 300. In this case, an area corresponding to the protruding surface 620 on the front surface of the rear cover 600 may be thicker than an area corresponding to the mounting surface 630 on the front surface of the rear cover 600.

Accordingly, the first surface 311 that meets the area corresponding to the protruding surface 620 on the rear surface of the ToF camera module 300 may efficiently transfer heat to the outside by contacting the front surface of the rear cover 600. That is, as described before with reference to FIGS. 6 to 9, the first surface 311 may be formed in an area where the light source 330 is formed.

More specifically, heat generated from the ToF camera module 300 may be transferred to the outside through the top cover 500 illustrated in FIGS. 11 and 12 via the rear cover 600.

Referring to FIGS. 11 and 12, the top cover 500 may include a heat sink 510, a first contact portion 520, and a second contact portion 530. The top cover 500 may transfer heat generated from the ToF camera module 300 or the electronic component 210 mounted on the PCB 200 to the outside, as described before with reference to FIGS. 1 and 2, and may be made of aluminum.

The heat sink 510 may be formed to extend in a first direction on the exterior of the top cover 500. The first direction may correspond to the x-axis direction, which is a front or rear direction. In addition, a plurality of heat sinks 510 may be arranged spaced apart from each other in a second direction perpendicular to the first direction. The second direction may correspond to the y-axis direction, which is the left-right direction.

Therefore, the top cover 500 may increase an area contacting air through the heat sink 510, and thus has the effect of efficiently transferring heat to the outside.

The first contact portion 520 may be formed on the front surface of the top cover 500 and meet at least a portion of the rear surface of the rear cover 600. That is, the rear cover 600 may contact the top cover 500 through the first contact portion 520, and thus transfer heat received from the ToF camera module 300 to the top cover 500.

The second contact portion 530 may be formed on the bottom of the top cover 500 and meet at least a portion of the electronic component 210 mounted on the PCB 200. That is, at least a portion of the electronic component 210 may come into contact with the top cover 500 through the second contact portion 530, and thus heat generated from the electronic component 210 may be transferred to the top cover 500. In this case, the electronic component 210 may indirectly meet the second contact portion 530 through a heat dissipation pad 900 (see FIG. 2). That is, the heat dissipation pad 900 may have one surface that meets the second contact portion 530 and the other surface that meets at least a portion of the electronic component 210, and thus transfer the heat generated from the electronic component 210 to the second contact portion 530.

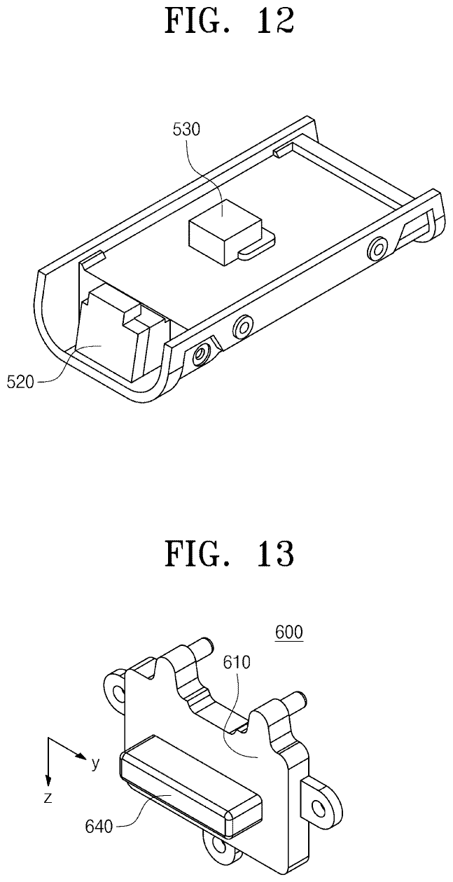

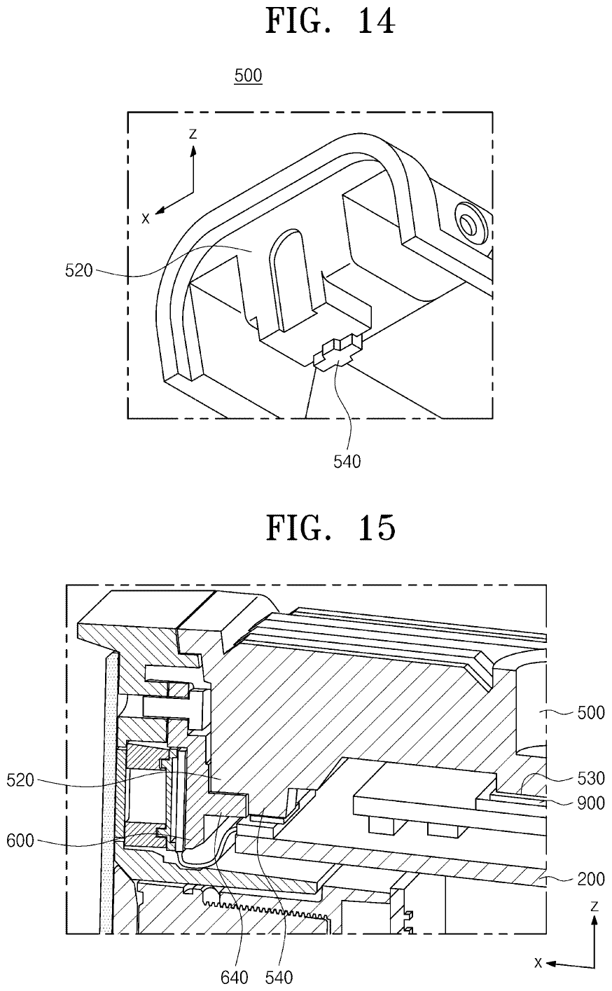

FIG. 13 is a diagram illustrating a rear cover according to embodiments. FIG. 14 is a diagram illustrating a top cover according to embodiments. FIG. 15 is a partial cross-sectional view illustrating a camera device according to embodiments. More specifically, FIG. 13 is a diagram illustrating the rear cover 600 viewed from the rear, and FIG. 14 is a diagram illustrating the top cover 500 viewed from the front.

Referring to FIG. 13, the rear cover 600 may include a rib 640 protruding from a rear surface thereof. The rib 640 may be formed to extend in the left and right directions.

Referring to FIG. 14, the top cover 500 may include a protrusion 540 formed to protrude on a bottom surface of the first contact portion 520. More specifically, the protrusion 540 may be formed relatively in the rear direction on the bottom surface of the first contact portion 520.

An area over which the rear cover 600 and the top cover 500 meet may be increased through the rib 640 and the protrusion 540, and as a result, the heat generated from the ToF camera module 300 may be efficiently transferred to the outside through the rear cover 600 and the top cover 500.

Referring to FIG. 15, a top surface of the rib 640 may meet the bottom surface of the first contact portion 520. A protruding surface of the rib 640 may meet the protrusion 540. That is, the rear cover 600 and the top cover 500 may meet at three portions. First, the rear cover 600 and the top cover 500 may meet, when a portion of the rear surface of the rear cover 600 meets the first contact portion 520. Secondly, the top surface of the rib 640 formed on the rear surface of the rear cover 600 and the bottom surface of the first contact portion 520 meet, so that the rear cover 600 and the top cover 500 may meet. Thirdly, the protruding surface of the rib 640 formed on the rear surface of the rear cover 600 and the front surface of the protrusion 540 protruding from the bottom surface of the first contact portion 520 meet, so that the rear cover 600 and the top cover 500 may meet.

Therefore, an area over which the rear cover 600 and the top cover 500 are in contact with each other may be increased through the rib 640 and the protrusion 540.

Further, referring to FIG. 15, the electronic component 210 mounted on the PCB 200 may transfer heat to the top cover 500 by contacting the second contact portion 530 through the heat dissipation pad 900. That is, the heat generated from the electronic component 210 may be transferred to the heat dissipation pad 900 in contact with the electronic component 210, and the transferred heat may be transferred to the second contact portion 530 in contact with the heat dissipation pad 900.

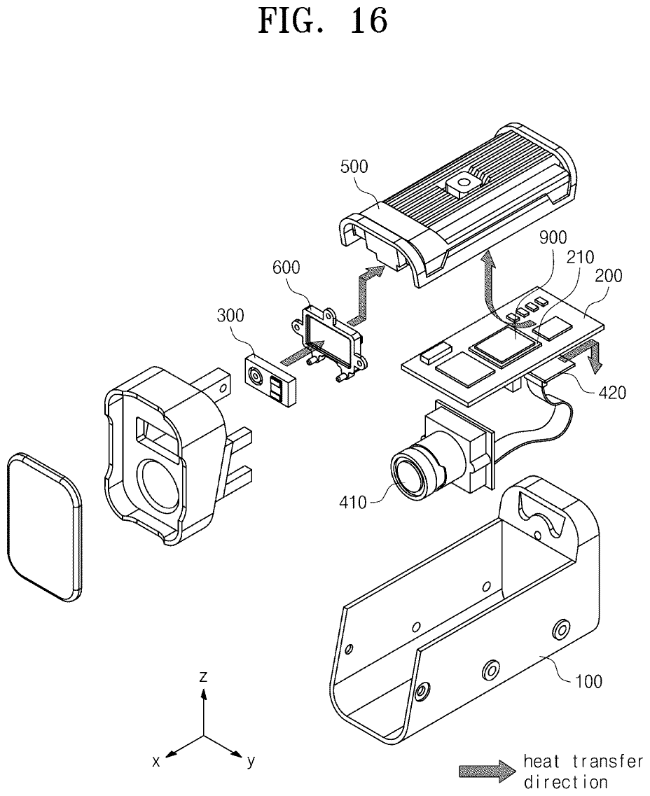

FIG. 16 is a diagram illustrating directions in which heat generated within a camera device is transferred according to embodiments.

Referring to FIG. 16, heat generated within the camera device 1000 according to the embodiments may have three causes, and include heat generated from the ToF camera module 300, heat generated from the RGB camera module 400, and heat generated from the electronic component 210 mounted on the PCB 200.

First, the heat generated from the ToF camera module 300 may be transferred to the top cover 500 through the rear cover 600 and consequently released to the outside. More specifically, as described above, the rear cover 600 covers the rear surface of the ToF camera module 300, and the rear cover 600 comes into contact with the first contact portion 520 of the top cover 500, so that the heat generated from the ToF camera module 300 may be ultimately transferred to the top cover 500.

Particularly, heat generated from the light source unit 330 in the ToF camera module 300 may be efficiently transferred, and thus the camera device 1000 according to the embodiments may prevent performance degradation caused by the heat.

Further, the heat generated from the electronic component 210 mounted on the PCB 200 may be transferred to the top cover 500 through the heat dissipation pad 900 and consequently released to the outside. More specifically, as described above, when the heat dissipation pad 900 comes into contact with the second contact portion 530 of the top cover 500, the heat generated from the electronic component 210 may be ultimately transferred to the top cover 500.

Further, the heat generated from a driving component 420 for driving the RGB camera module 400 may be transferred to the bottom of the body 100 rather than to the top cover 500 and consequently released to the outside. The driving component 420 may include an image signal processor (ISP) as a component for image processing of the RGB camera module 400.

Particularly, the driving component 420 may be located on the side of the other surface of the PCB 200, spaced apart from the PCB 200. Heat generated from the driving component 420 for driving the RGB camera module 400 may move downward, and thus may not affect the electronic component 210 mounted on one surface of the PCB 200.

Therefore, as the driving component 420 is disposed separately from the PCB 200, the camera device 1000 according to the embodiments has the effect of blocking heat generated from the driving component 420 from affecting other electronic components.

The preferred embodiments of the present disclosure have been described above to enable those skilled in the art to implement and practice the present disclosure. Although reference has been made to the preferred embodiments of the present disclosure, those skilled in the art will appreciate that various modifications and variations may be made to the present disclosure without departing from the scope of the present disclosure. For example, those skilled in the art may use individual components of the above-described embodiments in combination.

Accordingly, the present disclosure is not intended to be limited to the embodiments set forth herein, but is to be accorded the broadest scope consistent with the principles and features disclosed herein.

What is claimed is:

1. A time of flight (ToF) camera module comprising:
a light source unit located a first side of a first substrate;
a ToF lens unit configured to receive light emitted from the light source unit; and
a ToF sensor unit located at a first side of a second substrate connected to the first substrate by a first connector, and configured to receive light passing through the ToF lens unit;
wherein the light source unit and the ToF lens unit are located to be aligned along a first layer, and the ToF sensor unit is located to be aligned along a second layer different from the first layer.

2. The ToF camera module of claim 1, further comprising a housing,
wherein a space is defined in the housing toward a second side of the first substrate.

3. The ToF camera module of claim 2, wherein the second substrate comprises an area where the ToF sensor unit is located and a cut out area comprising an opening, and
wherein the space is defined by the opening and the second side of the first substrate.

4. The ToF camera module of claim 1, wherein the first connector is flexible to connect the first substrate and the second substrate.

5. The ToF camera module of claim 1, further comprising a housing configured to accommodate the ToF sensor unit therein, wherein the light source unit and the ToF lens unit are at least partially exposed at a front of the housing.

6. The ToF camera module of claim 5, wherein a rear of the housing comprises a first surface and a second surface in a stepped configuration with the first surface.

7. The ToF camera module of claim 1, further comprising:
a third substrate configured to receive externally provided power; and
a second connector configured to connect the third substrate and the second substrate,
wherein the first substrate and the second substrate are configured to receive power from the third substrate through the second connector.

8. A camera device comprising:
a body; and
a time of flight (ToF) camera module located in the body and comprising:
a light source unit located at a first side of a first substrate;
a ToF lens unit configured to receive light emitted from the light source unit; and
a ToF sensor unit located at a first side of a second substrate connected to the first substrate by a first connector, and configured to receive light passing through the ToF lens unit;
wherein a space is defined toward a second side of the first substrate, and
wherein the light source unit and the ToF lens unit are located to be aligned along a first layer, and the ToF sensor unit is located to be aligned along a second layer different from the first layer.

9. The camera device of claim 8, wherein the second substrate comprises an area where the ToF sensor unit is located and a cut out area comprising an opening, and
wherein the space is defined by the opening and the second side of the first substrate.

10. The camera device of claim 8, wherein the ToF camera module further comprises a housing configured to accommodate the ToF sensor unit therein, wherein the light source unit and the ToF lens unit are at least partially exposed at a front of the housing,
wherein a rear of the housing comprises a first surface and a second surface in a stepped configuration with the first surface, and
wherein the space is defined by the first surface of the rear of the housing inside the body.

11. The camera device of claim 10, further comprising a rear cover comprising a front cover surface configured to contact the rear of the ToF camera module.

12. The camera device of claim 11, wherein the front cover surface of the rear cover comprises a protruding surface configured to contact the first surface and a mounting surface configured to contact the second surface, and
wherein the protruding surface is formed to protrude further forward than the mounting surface.

13. The camera device of claim 11, further comprising a top cover coupled with the body and comprising a heat sink with a plurality of fins extending along a first direction at an exterior thereof,
wherein the fins are spaced apart from each other along a second direction perpendicular to the first direction.

14. The camera device of claim 13, wherein the top cover further comprises a first contact portion configured to contact a surface of the rear cover.

15. The camera device of claim 14, wherein the rear cover comprises a rib protruding from a rear of the rear cover and comprising a top surface configured to contact a bottom surface of the first contact portion, and
wherein the top cover further comprises a protrusion formed to protrude from the bottom surface of the first contact portion and comprising a front surface of the protrusion configured to contact a rear surface of the rib.

16. The camera device of claim 8, further comprising:
a printed circuit board (PCB); and
a red, green, blue (RGB) camera module located in the body, and
wherein the ToF camera module is located at a first side of the PCB,
wherein the RGB camera module is located at a second side of the PCB opposite the first side of the PCB, and
wherein a front of the ToF camera module and a front of the RGB camera module are aligned on a single plane.

17. The camera device of claim 16, wherein the RGB camera module comprises a processor for driving the RGB camera module, and
wherein the processor is located at the second side of the PCB.

18. The camera device of claim 16, further comprising a front cover coupled with the body,
wherein the front cover is configured to define accommodation portions corresponding to the ToF camera module and the RGB camera module.

19. The camera device of claim 18, further comprising a front glass covering a front of the front cover,
wherein a mask is formed at portions of the front glass other portions corresponding to the ToF camera module and the RGB camera module.
